(19) United States
(12) Patent Application Publication
(10) Pub. No.: US 2025/0126858 A1
(43) Pub. Date: Apr. 17, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Hsin-Che CHIANG, Taipei City (TW); Chi-Wei WU, Hsinchu City (TW); Pang-Hsuan LIU, Taoyuan City (TW); Wei-Chih KAO, Taipei (TW); Jeng-Ya YEH, New Taipei City (TW); Mu-Chi CHIANG, Hsinchu (TW); Jhon-Jhy LIAW, Zhudong Township (TW)

(21) Appl. No.: 18/488,448

(22) Filed: Oct. 17, 2023

(51) Int. Cl. H01L 29/06; H01L 29/423; H01L 29/66; H01L 29/775; H01L 29/786

(52) U.S. Cl. CPC H10D 62/121; H10D 30/014; H10D 30/43; H10D 30/6735; H10D 30/6757; H10D 64/017

(57) ABSTRACT

Semiconductor structures and methods for manufacturing the same are provided. The semiconductor structure includes first nanostructures formed over a substrate along a first direction, and second nanostructures formed over the substrate along the first direction. The semiconductor structure includes a first gate structure formed over the first nanostructures along a second direction, and a second gate structure formed over the second nanostructures along the second direction. The semiconductor structure also includes a dielectric wall structure between the first gate structure and the second gate structure along the second direction. The dielectric wall structure includes a top portion and a bottom portion, and a top width of a top surface of the top portion is smaller than a bottom width of a bottom surface of the bottom portion of the dielectric wall structure.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1E illustrate perspective views of intermediate stages of manufacturing a semiconductor structure in accordance with some embodiments.

FIG. 2 shows a top-view representation of the semiconductor structure, in accordance with some embodiments.

FIGS. 3A-1 to 3F-1 illustrate cross-sectional representations of various stages of manufacturing the semiconductor structure shown along line A-A′ in FIG. 1E and in FIG. 2, in accordance with some embodiments.

FIGS. 3A-2 to 3F-2 illustrate cross-sectional representations of various stages of manufacturing the semiconductor structure shown along line B-B′ in FIG. 1E and in FIG. 2, in accordance with some embodiments.

FIGS. 3A-3 to 3F-3 illustrate cross-sectional representations of various stages of manufacturing the semiconductor structure shown along line C₁-C₁′ in FIG. 1E and in FIG. 2, in accordance with some embodiments.

FIGS. 4A to 4J illustrate cross-sectional representations of various stages of manufacturing the semiconductor structure shown along line in B-B′ in FIG. 1E and in FIG. 2 after FIG. 3F-2, in accordance with some embodiments.

FIG. 5 shows a top-view representation of the semiconductor structure along the line DD′ in FIG. 4J, in accordance with some embodiments.

FIGS. 6A to 6C illustrate cross-sectional representations of various stages of manufacturing a semiconductor structure shown along line B-B′ in FIG. 1E and FIG. 2, in accordance with some embodiments.

FIG. 7 illustrates a cross-sectional representation of a semiconductor structure shown along line B-B′ in FIG. 1E and FIG. 2, in accordance with some embodiments.

FIG. 8 illustrates a cross-sectional representation of a semiconductor structure shown along line B-B′ in FIG. 1E and FIG. 2, in accordance with some embodiments.

FIG. 9 shows a top-view representation of a semiconductor structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structures may include a first fin structure and a second fin structure formed over a substrate. The first fin structure includes first nanostructures, and the second fin structure includes second nanostructures along a first direction (e.g. x-axis). A first gate structure formed over the first nanostructures along the second direction (e.g. y-direction) and a second gate structure formed along the second direction (e.g. y-direction). The dielectric wall structure is between the first fin structure and the second fin structure. The dummy gate dielectric layer is between the dielectric wall structure and the first fin structure. Since one side of the nanostructure is in direct contact with the dummy gate dielectric layer, the effective width (W_{eff}) of nanostructure (or channel layer) is reduced. When the effective width (W_{eff}) of nanostructure (or channel layer) is reduced, the current of the semiconductor layer can be reduced for better power efficiency. Therefore, the performance of the semiconductor structure is improved. The source/drain (S/D) structure or region(s) may refer to a source or a drain, individually or collectively dependent upon the context.

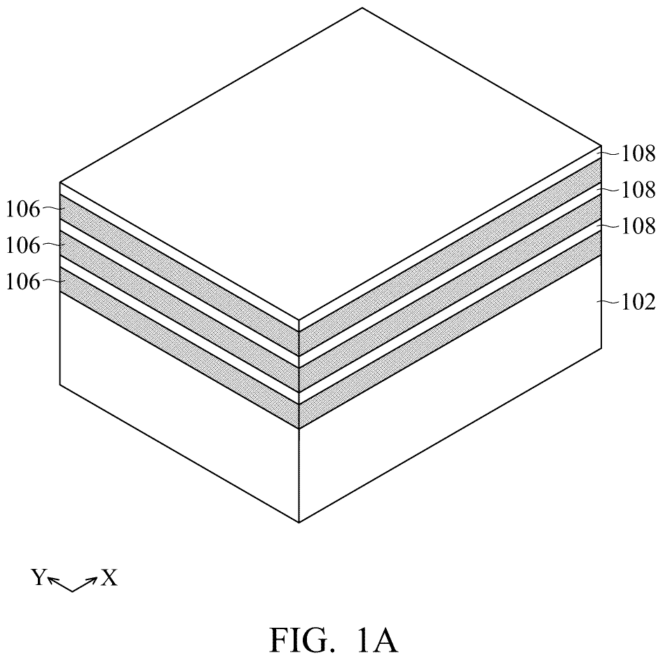

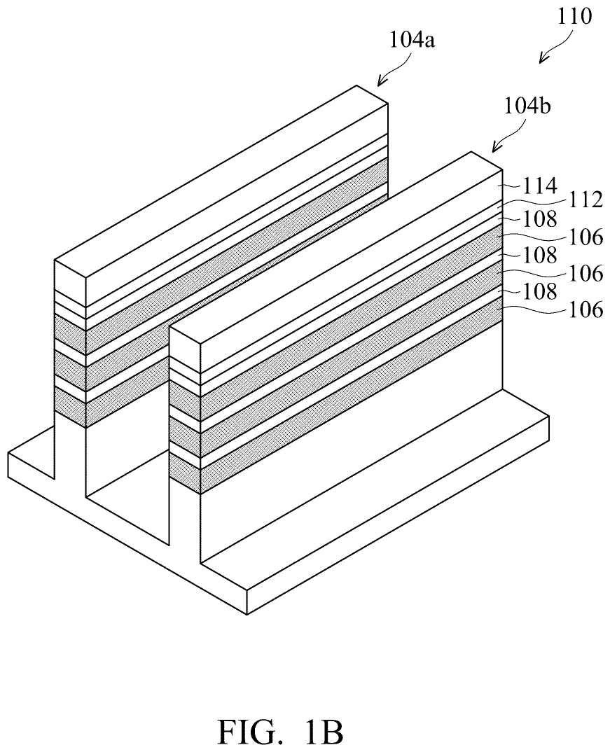

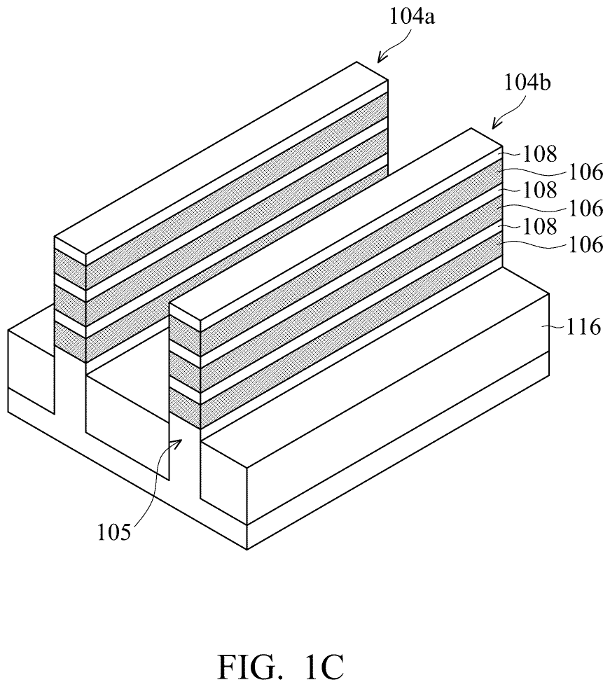

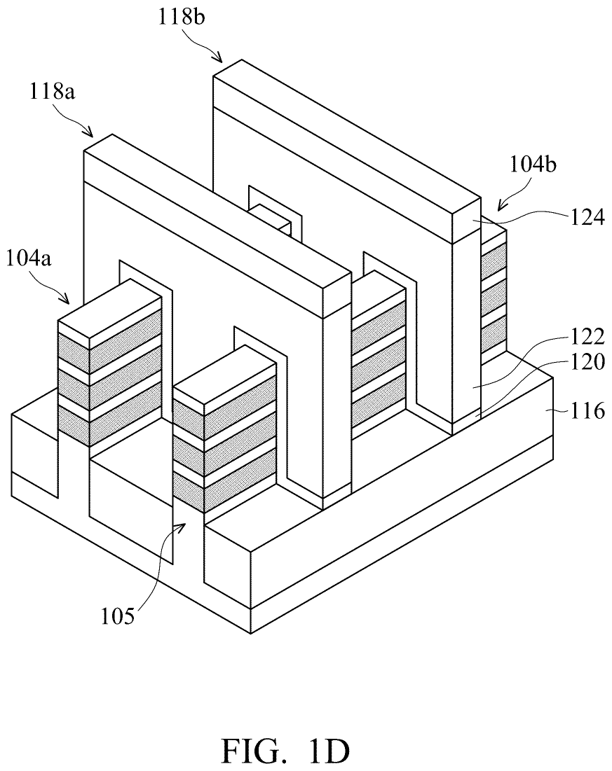

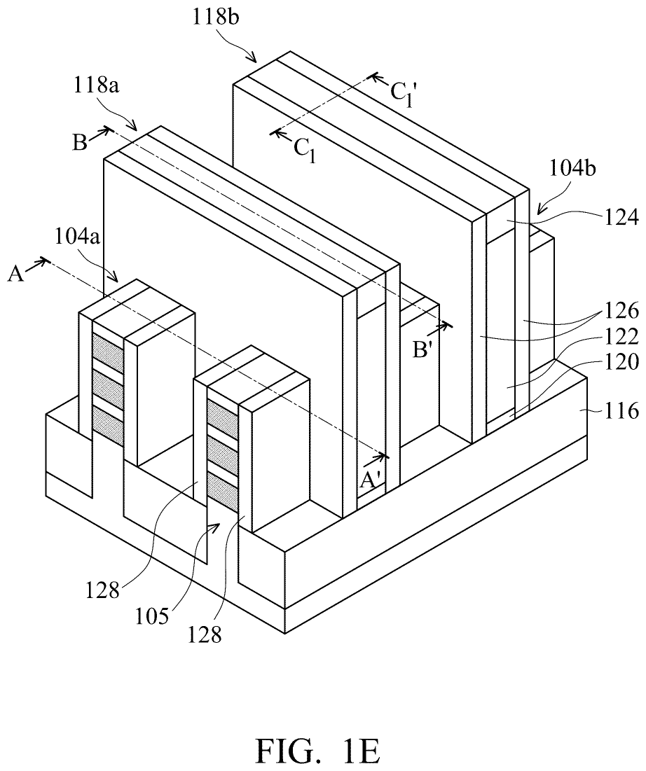

FIGS. 1A to 1E illustrate perspective views of intermediate stages of manufacturing a semiconductor structure 100a, in accordance with some embodiments. As shown in FIG. 1A, first semiconductor material layers 106 and second semiconductor material layers 108 are formed over a substrate 102.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

Afterwards, as shown in FIG. 1B, after the first semiconductor material layers 106 and the second semiconductor material layers 108 are formed as a semiconductor material stack over the substrate 102, the semiconductor material stack is patterned to form a first fin structure 104a and a second fin structure 104b, in accordance with some embodiments. In some embodiments, each of the first fin structure 104a and a second fin structure 104b includes a base fin structure 105 and the semiconductor material stack of the first semiconductor material layers 106 and the second semiconductor material layers 108.

In some embodiments, the patterning process includes forming a mask structure 110 over the semiconductor material stack, and etching the semiconductor material stack and the underlying substrate 102 through the mask structure 110. In some embodiments, the mask structure 110 is a multilayer structure including a pad oxide layer 112 and a nitride layer 114 formed over the pad oxide layer 112. The pad oxide layer 112 may be made of silicon oxide, which is formed by thermal oxidation or chemical vapor deposition (CVD), and the nitride layer 114 may be made of silicon nitride, which is formed by chemical vapor deposition (CVD), such as low-temperature chemical vapor deposition (LPCVD) or plasma-enhanced CVD (PECVD).

Next, as shown in FIG. 1C, after the first fin structure 104a and the second fin structure 104b is formed, an isolation structure 116 is formed around first fin structure 104a and the second fin structure 104b, and the mask structure 110 is removed, in accordance with some embodiments. The isolation structure 116 is configured to electrically isolate active regions (e.g. the first fin structure 104a and the second fin structure 104b) of the semiconductor structure 100a and is also referred to as shallow trench isolation (STI) feature in accordance with some embodiments.

The isolation structure 116 may be formed by depositing an insulating layer over the substrate 102 and recessing the insulating layer so that the first fin structure 104a and the second fin structure 104b is protruded from the isolation structure 116. In some embodiments, the isolation structure 116 is made of silicon oxide, silicon nitride, silicon oxynitride (SiON), another suitable insulating material, or a combination thereof. In some embodiments, a dielectric liner (not shown) is formed before the isolation structure 116 is formed, and the dielectric liner is made of silicon nitride and the isolation structure formed over the dielectric liner is made of silicon oxide.

Afterwards, as shown in FIG. 1D, after the isolation structure 116 is formed, first dummy gate structures 118a and second dummy gate structures 118b are formed across the first fin structure 104a and the second fin structure 104b and extend over the isolation structure 116, in accordance with some embodiments. The first dummy gate structures 118a and the second dummy gate structures 118b may be used to define the source/drain (S/D) regions and the channel regions of the resulting semiconductor structure 100a.

In some embodiments, each of the first dummy gate structures 118a and each of the second dummy gate structures 118b includes dummy gate dielectric layers 120 and dummy gate electrode layers 122. In some embodiments, the dummy gate dielectric layers 120 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layers 120 are formed using thermal oxidation, chemical vapor deposition (CVD), atomic vapor deposition (ALD), physical vapor deposition (PVD), another suitable method, or a combination thereof.

In some embodiments, the conductive material includes polycrystalline-silicon (poly-Si), poly-crystalline silicon-germanium (poly-SiGe), metallic nitrides, metallic silicides, metals, or a combination thereof. In some embodiments, the dummy gate electrode layers 122 are formed using chemical vapor deposition (CVD), physical vapor deposition (PVD), or a combination thereof.

In some embodiments, hard mask layers 124 are formed over the dummy gate structures 118. In some embodiments, the hard mask layers 124 include multiple layers, such as an oxide layer and a nitride layer. In some embodiments, the oxide layer is silicon oxide, and the nitride layer is silicon nitride.

The formation of the dummy gate structures 118 may include conformally forming a dielectric material as the dummy gate dielectric layers 120. Afterwards, a conductive material may be formed over the dielectric material as the dummy gate electrode layers 122, and the hard mask layer 124 may be formed over the conductive material. Next, the dielectric material and the conductive material may be patterned through the hard mask layer 124 to form the dummy gate structures 118.

Next, as shown in FIG. 1E, after the dummy gate structures 118 are formed, gate spacer layers 126 are formed along and covering opposite sidewalls of the dummy gate structure 118 and fin spacer layers 128 are formed along and covering opposite sidewalls of the source/drain regions of the fin structure 104, in accordance with some embodiments.

The gate spacer layers 126 may be configured to separate source/drain (S/D) structures from the first dummy gate structure 118a, the second dummy gate structures 118b and support the first dummy gate structure 118a, the second dummy gate structures 118b, and the fin space layers 128 may be configured to constrain a lateral growth of subsequently formed source/drain structure and support the first fin structure 104a and the second fin structure 104b.

In some embodiments, the gate spacer layers 126 and the fin spacer layers 128 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. The formation of the gate spacer layers 126 and the fin spacer layers 128 may include conformally depositing a dielectric material covering the first dummy gate structure 118a, the second dummy gate structure 118b, the first fin structure 104a, the second fin structure 104b and the isolation structure 116 over the substrate 102, and performing an anisotropic etching process, such as dry plasma etching, to remove the dielectric layer covering the top surfaces of the first dummy gate structure 118a, the second dummy gate structure 118b, the first fin structure 104a, the second fin structure 104b, and portions of the isolation structure 116.

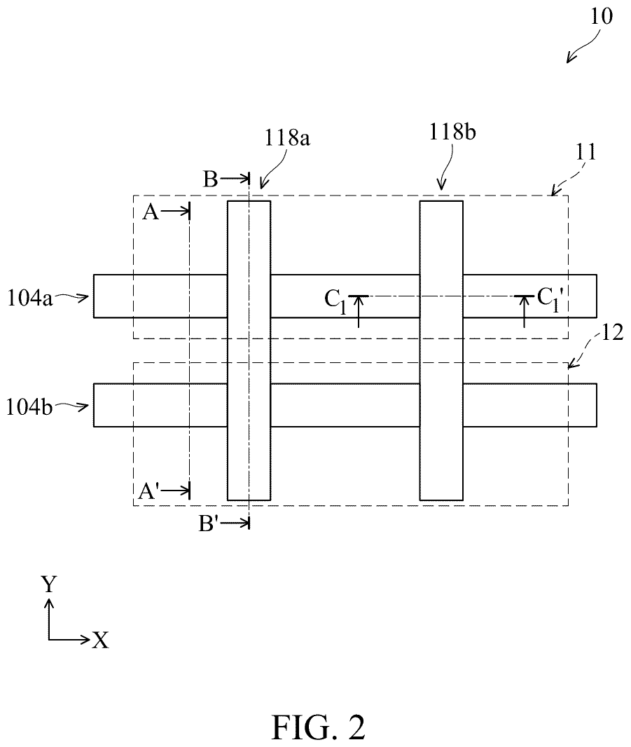

FIG. 2 shows a top-view representation of the semiconductor structure 100a, in accordance with some embodiments. As shown in FIG. 2, the substrate 102 includes a first region 10, and the first region 10 includes a first sub-region 11 and a second sub-region 12. The first fin structure 104a is formed in the first sub-region 11 along a first direction (e.g. X-axis), and the second fin structure 104b is formed in the second sub-region 12 along the first direction (e.g. X-axis). A first dummy gate structure 118a and a second dummy gate structure 118b are formed along a second direction (e.g. Y-axis). The first dummy gate structure 118a and the second dummy gate structure 118b are formed across the first fin structure 104a and the second fin structure 104b.

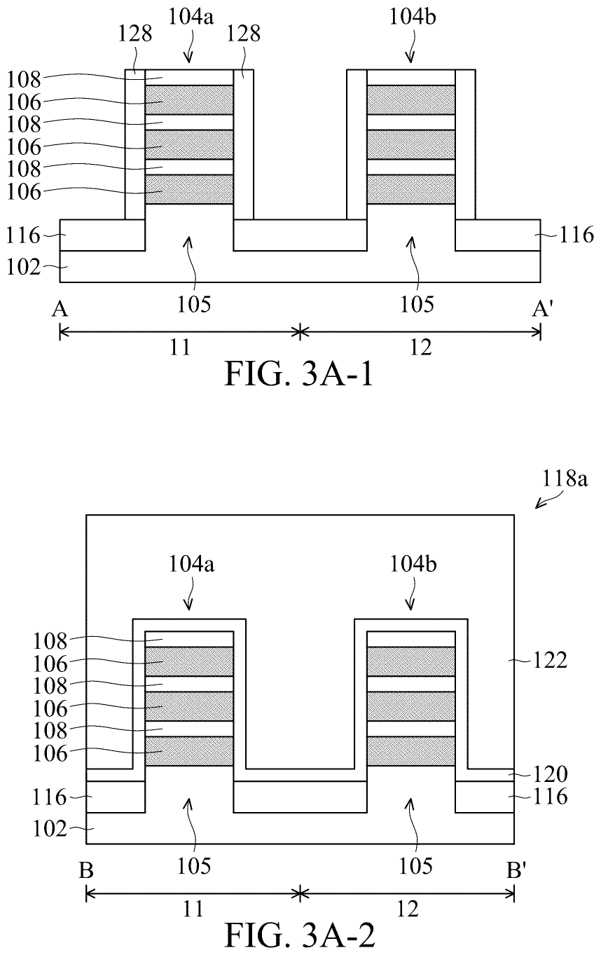

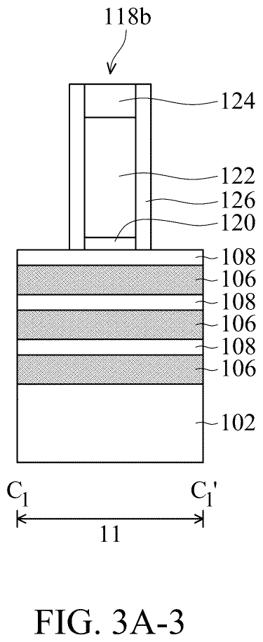

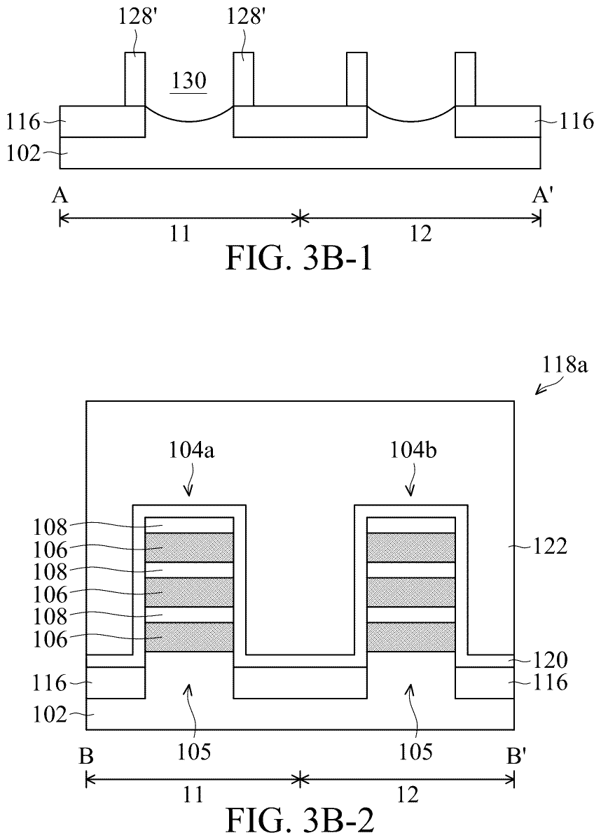

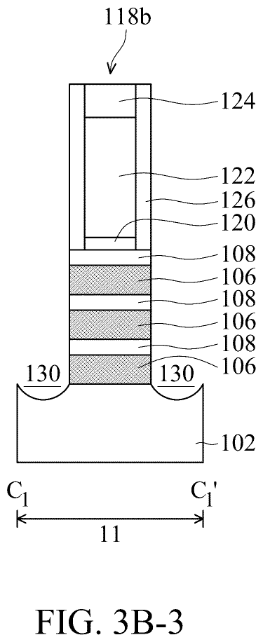

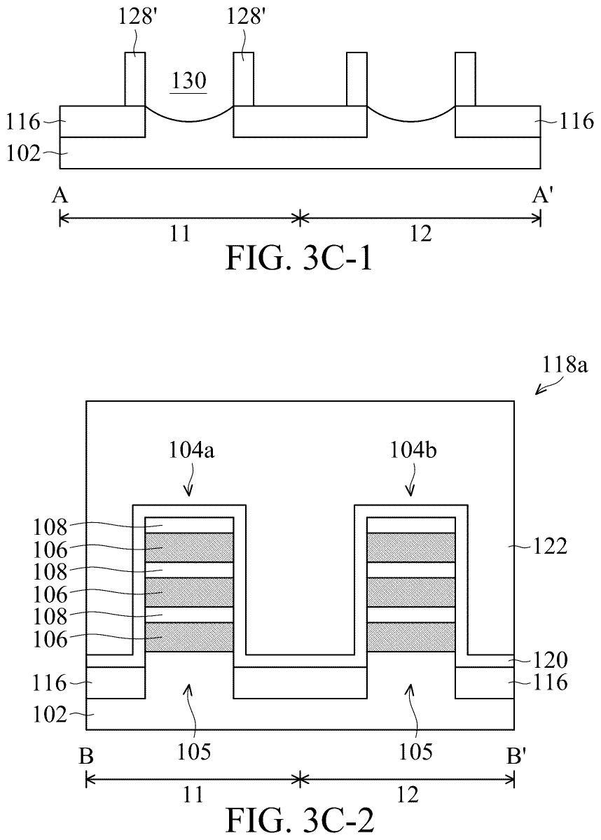

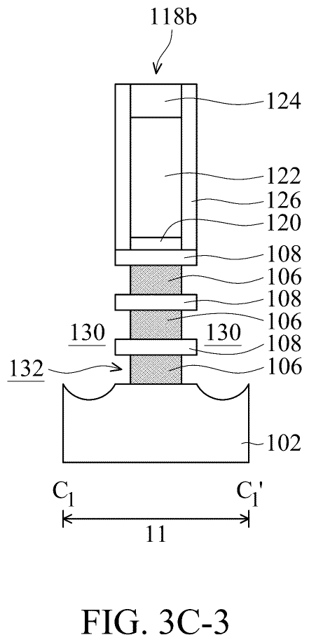

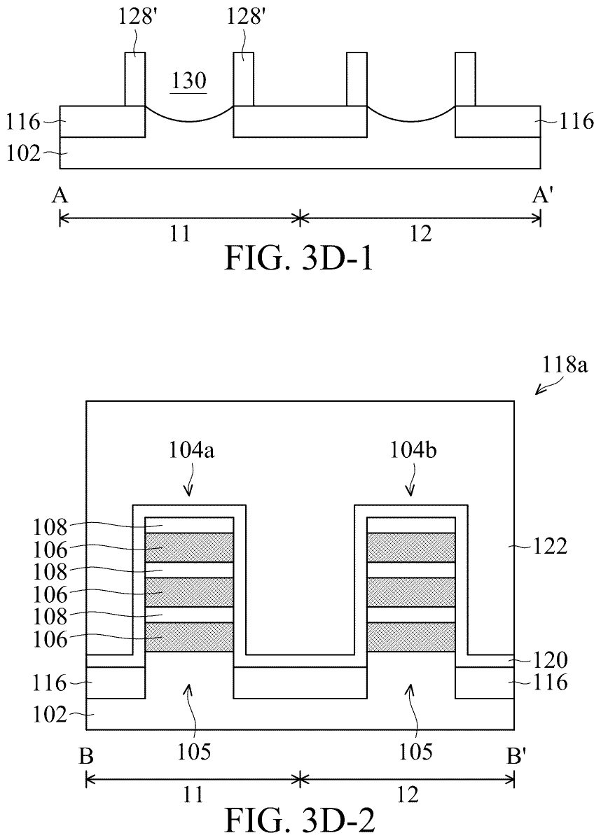

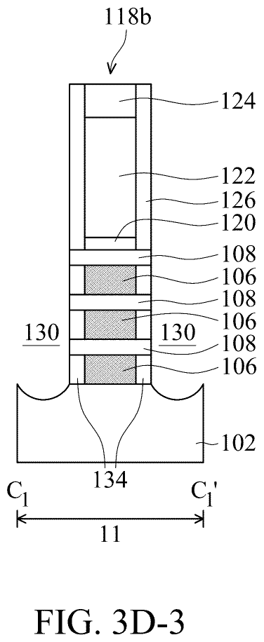

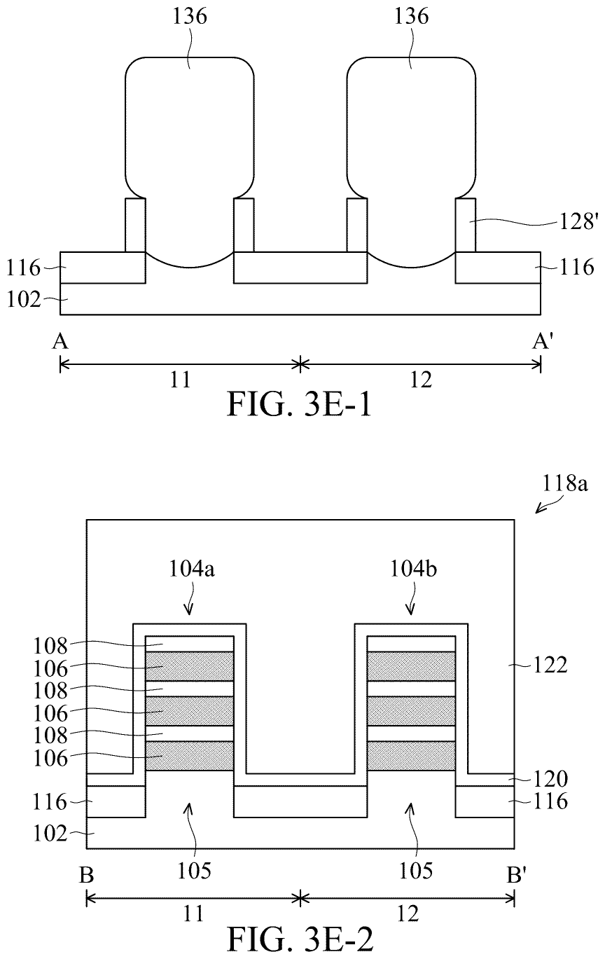

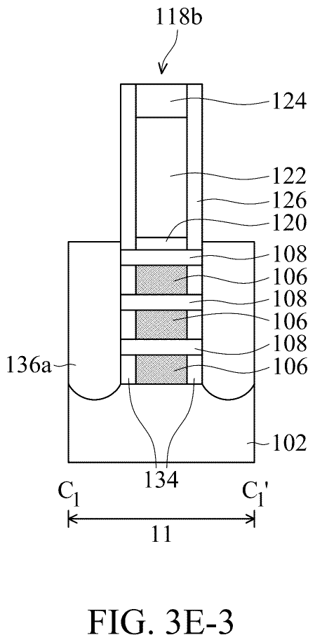

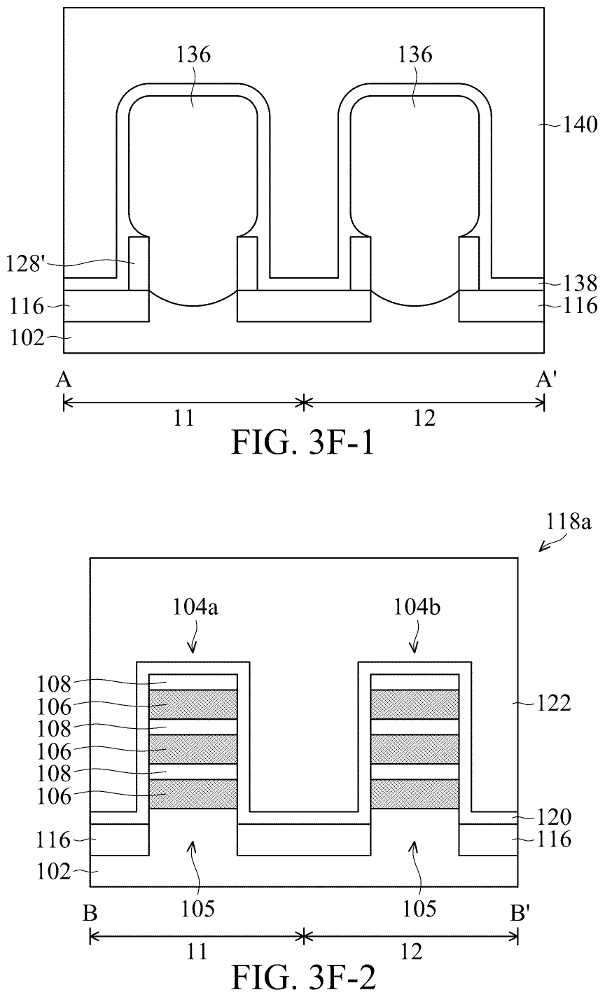

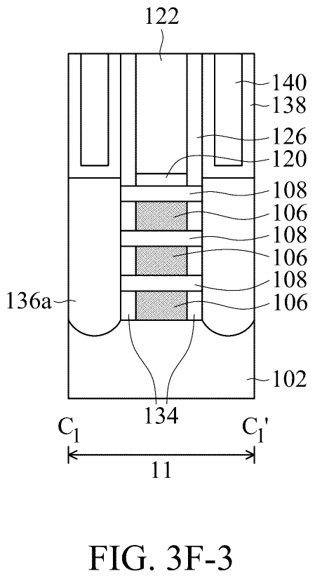

FIGS. 3A-1 to 3F-1 illustrate cross-sectional representations of various stages of manufacturing the semiconductor structure 100a shown along line A-A′ in FIG. 1E and in FIG. 2, in accordance with some embodiments. FIGS. 3A-2 to 3F-2 illustrate cross-sectional representations of various stages of manufacturing the semiconductor structure 100a shown along line B-B′ in FIG. 1E and in FIG. 2, in accordance with some embodiments. FIGS. 3A-3 to 3F-3 illustrate cross-sectional representations of various stages of manufacturing the semiconductor structure 100a shown along line C₁-C₁′ in FIG. 1E and in FIG. 2, in accordance with some embodiments.

More specifically, FIG. 3A-1 illustrates the cross-sectional representation shown along line A-A″ in FIG. 1E and FIG. 2. FIG. 3A-2 illustrates the cross-sectional representation shown along line B-B′ in FIG. 1E and FIG. 2 in accordance with some embodiments. FIG. 3A-3 illustrates the cross-sectional representation shown along line C₁-C₁′ in FIG. 1E and in FIG. 2.

Next, as shown in FIGS. 3B-1, 3B-2 and 3B-3, after the gate spacer layers 126 and the fin spacer layers 128 are formed, the source/drain (S/D) regions of the fin structure 104 are recessed to form source/drain (S/D) recesses 130, as shown in in accordance with some embodiments. More specifically, the first semiconductor material layers 106 and the second semiconductor material layers 108 not covered by the dummy gate structures 118 and the gate spacer layers 126 are removed, in accordance with some embodiments. In addition, some portions of the base fin structure 105 are also recessed to form curved top surfaces, as shown in FIG. 3B-1 in accordance with some embodiments.

In some embodiments, the first fin structure 104a and the second fin structure 104b are recessed by performing an etching process. The etching process may be an anisotropic etching process, such as dry plasma etching, and the first dummy gate structure 118a, the second dummy gate structure 118b and the gate spacer layers 126 are used as etching masks during the etching process. In some embodiments, the fin spacer layers 128 are also recessed to form lowered fin spacer layers 128′.

Afterwards, as shown in FIGS. 3C-1, 3C-2 and 3C-3, after the source/drain (S/D) recesses 130 are formed, the first semiconductor material layers 106 exposed by the source/drain recesses 130 are laterally recessed to form notches 132, in accordance with some embodiments.

In some embodiments, an etching process is performed on the semiconductor structure 100a to laterally recess the first semiconductor material layers 106 of the fin structure 104 from the source/drain recesses 130. In some embodiments, during the etching process, the first semiconductor material layers 106 have a greater etching rate (or etching amount) than the second semiconductor material layers 108, thereby forming notches 132 between adjacent second semiconductor material layers 108. In some embodiments, the etching process is an isotropic etching such as dry chemical etching, remote plasma etching, wet chemical etching, another suitable technique, and/or a combination thereof.

Next, as shown in FIGS. 3D-1, 3D-2 and 3D-3, inner spacers 134 are formed in the notches 132 between the second semiconductor material layers 108, in accordance with some embodiments. The inner spacers 134 are configured to separate the source/drain (S/D) structures and the gate structures formed in subsequent manufacturing processes in accordance with some embodiments. In some embodiments, the inner spacers 134 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer layer 134 is formed by a deposition process, such as chemical vapor deposition (CVD) process, atomic layer deposition (ALD) process, another applicable process, or a combination thereof.

Afterwards, as shown in FIGS. 3E-1, 3E-2 and 3E-3, after the inner spacers 134 are formed, a source/drain (S/D) structure 136 is formed in the S/D recesses 130, in accordance with some embodiments.

In some embodiments, the source/drain (S/D) structure 136 is formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof. In some embodiments, the source/drain (S/D) structure 136 is made of any applicable material, such as Ge, Si, GaAs, AlGaAs, SiGe, GaAsP, SiP, SiC, SiCP, or a combination thereof.

In some embodiments, the source/drain (S/D) structure 136 is in-situ doped during the epitaxial growth process. For example, the source/drain (S/D) structure 136 may be the epitaxially grown SiGe doped with boron (B). For example, the source/drain (S/D) structure 136 may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the source/drain (S/D) structure 136 is doped in one or more implantation processes after the epitaxial growth process

Afterwards, as shown in FIGS. 3F-1, 3F-2 and 3F-3, a contact etch stop layer (CESL) 138 is conformally formed to cover the S/D structures 136, and an interlayer dielectric (ILD) layer 140 is formed over the contact etch stop layers 138, in accordance with some embodiments.

In some embodiments, the contact etch stop layer 138 is made of a dielectric materials, such as silicon nitride, silicon oxide, silicon oxynitride, another suitable dielectric material, or a combination thereof. The dielectric material for the contact etch stop layers 138 may be conformally deposited over the semiconductor structure by performing chemical vapor deposition (CVD), ALD, other application methods, or a combination thereof.

The ILD layer 140 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 140 may be formed by chemical vapor deposition (CVD), physical vapor deposition, (PVD), atomic layer deposition (ALD), or other applicable processes.

After the contact etch stop layer 138 and the ILD layer 140 are deposited, a planarization process such as CMP or an etch-back process may be performed until the gate electrode layers 120 of the dummy gate structures 118 are exposed, as shown in FIG. 3F-3 in accordance with some embodiments.

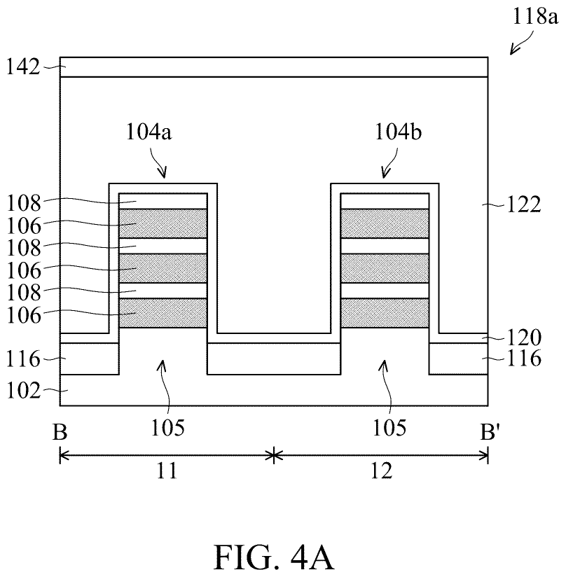

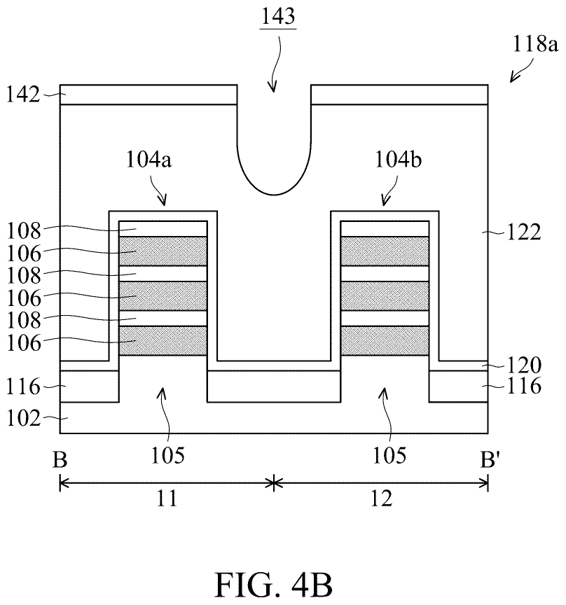

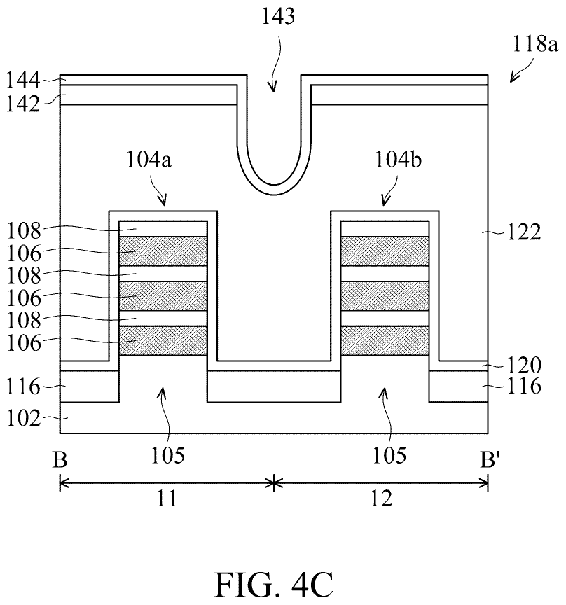

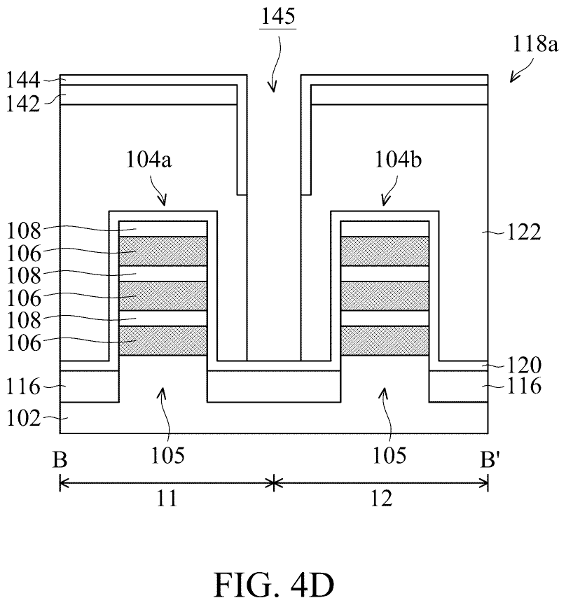

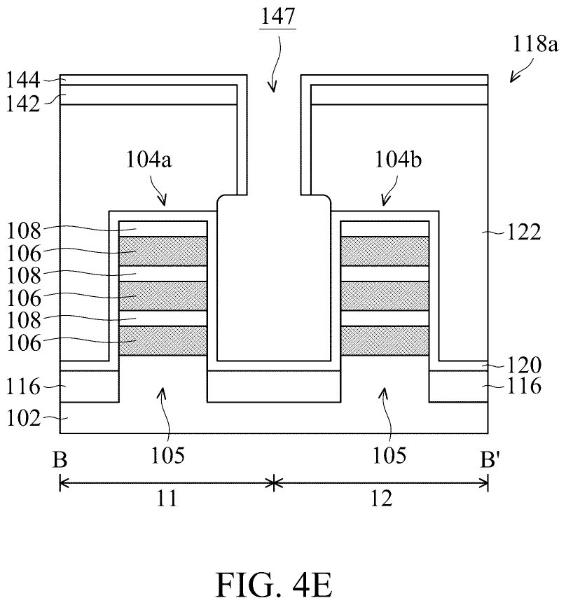

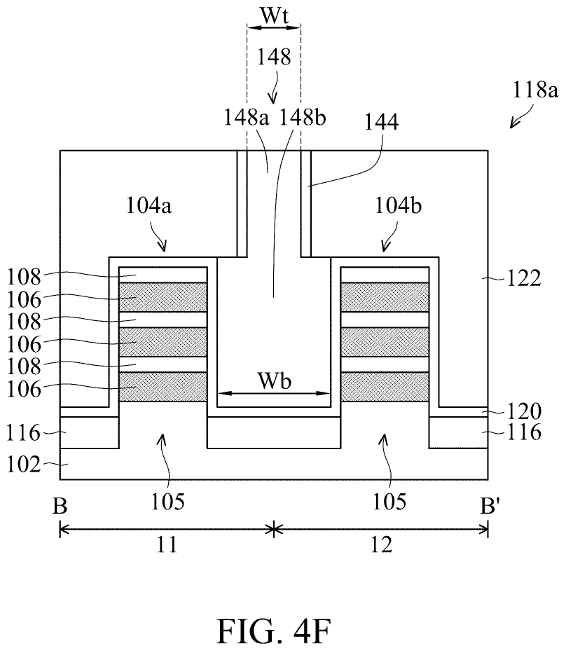

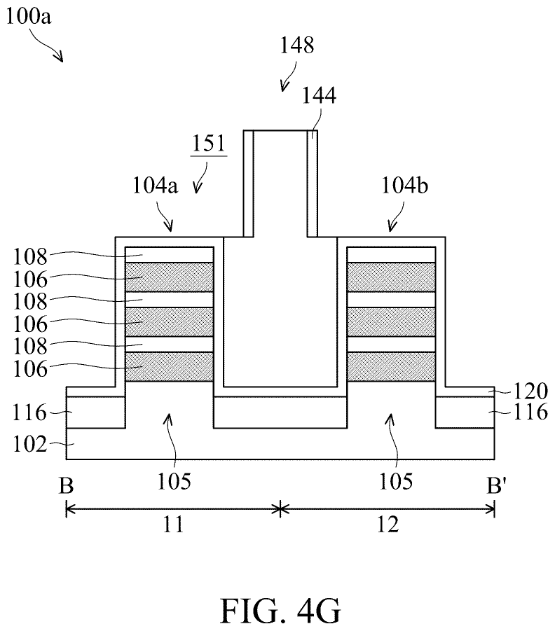

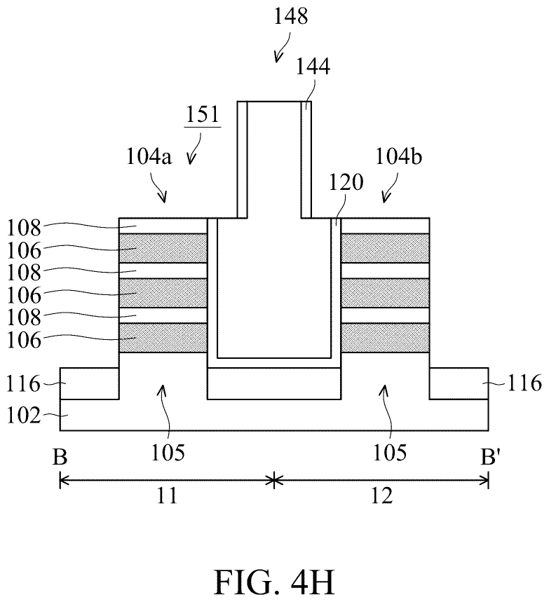

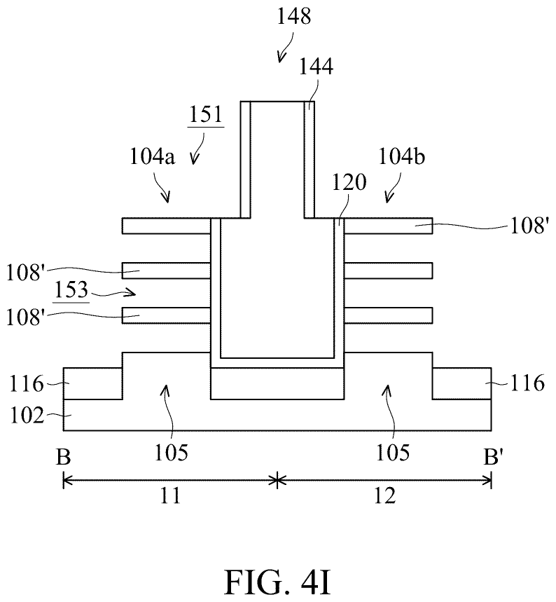

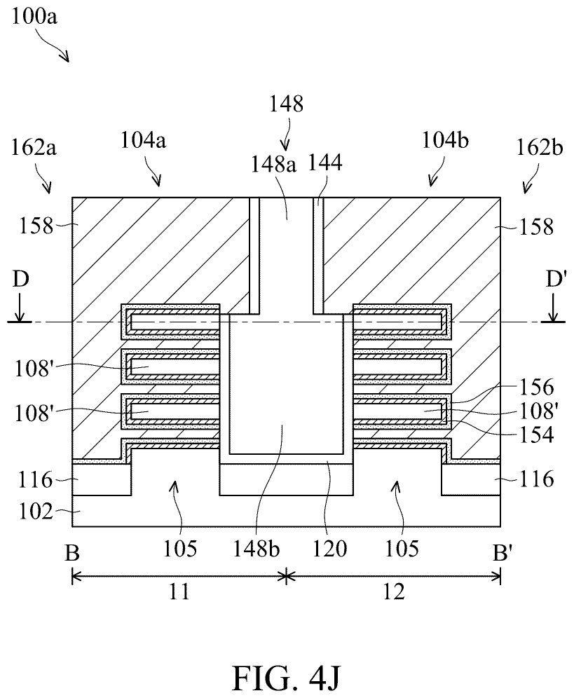

FIGS. 4A to 4J illustrate cross-sectional representations of various stages of manufacturing the semiconductor structure 100a shown along line in B-B′ in FIG. 1E and in FIG. 2 after FIG. 3F-2, in accordance with some embodiments.

As shown in FIG. 4A, a hard mask layer 142 is formed on the first dummy gate structure 118a, in accordance with some embodiments. More specifically, the hard mask layer 142 is formed on the dummy gate electrode layer 122.

In some embodiments, the hard mask layer 142 is made of silicon nitride, silicon oxynitride, or another applicable material. In some embodiments, the hard mask layer 142 is formed by chemical vapor deposition (CVD), physical vapor deposition, (PVD), atomic layer deposition (ALD), or other applicable processes.

Next, as shown in FIG. 4B, the hard mask layer 142 is patterned, and the top portion of the dummy gate electrode layer 122 is removed to form an opening 143, in accordance with some embodiments. The bottommost surface of the opening 143 is higher than the topmost surface of the first fin structure 104a. More specifically, the bottommost surface of the opening 143 is higher than the topmost surface of the topmost second semiconductor material layer 108. The hard mask layer 142 is patterned by using a photolithography process and an etching process.

Afterwards, as shown in FIG. 4C, a protection layer 144 is formed in the opening 143 and on the hard mask layer 141, in accordance with some embodiments. The protection layer 144 lines along the sidewall surfaces of the opening 143. The protection layer 144 is used to protect the dummy gate electrode layer 122 from being damaged after the following processes.

The protection layer 144 with respect to the dummy gate electrode layer 122 has high etching selectivity. Therefore, when the portion of the dummy gate electrode layer 122 is removed while the protection layer 144 is not removed.

In some embodiments, the protection layer 144 is made of silicon nitride (SiN), silicon carbide (SiC), silicon oxynitride (SiON), silicon carbon nitride (SiCN), silicon oxide carbonitride (SiOCN), and/or a combination thereof. In some embodiments, the protection layer 144 is formed by chemical vapor deposition (CVD), physical vapor deposition, (PVD), atomic layer deposition (ALD), or other applicable processes.

Next, as shown in FIG. 4D, the bottom portion of the dummy gate electrode layer 122 below the opening 143 is further removed to elongate the depth of the opening 143 to form a recess 145, in accordance with some embodiments. As a result, the dummy gate dielectric layer 120 is exposed by the recess 145. The depth of the recess 145 is greater than the depth of the opening 143.

In some other embodiments, a portion of the dummy gate dielectric layer 120 is removed to expose the top surface of the isolation structure 116. In some other embodiments, a portion of the dummy gate dielectric layer 120 and a portion of the isolation structure 116 are exposed.

In some embodiments, the bottom portion of the dummy gate electrode layer 122 below the opening 143 is further removed by an etching process, and the process is a dry etching process. In some embodiments, the etching gas used in the dry etching process includes using fluorine (F)-containing gas, chloride (CI)-containing gas hydrogen bromide (HBr) or another applicable gas.

Next, as shown in FIG. 4E, the sidewall portion of the dummy gate electrode layer 122 is removed to enlarge the width of the recess 145 to form a trench 147, in accordance with some embodiments. In some embodiments, the width of the trench 147 is greater than the width of the recess 145.

Since the protection layer 144 has a high etching selectivity with respect to the dummy gate electrode layer 122, the sidewall portion of the dummy gate electrode layer 122 which is protected by the protection layer 144 is not removed. Therefore, the trench 147 is a self-aligned structure. The trench 147 has a top portion and a bottom portion, and the width of the top portion is smaller than the width of the bottom portion of the trench 147.

In addition, the dummy gate dielectric layer 120 has a high etching selectivity with respect to the dummy gate electrode layer 122, and therefore the dummy gate dielectric layer 120 is not removed while the dummy gate electrode layer 122 is removed. Therefore, the dummy gate electrode layer 122 is exposed by the trench 147.

In some embodiments, the sidewall portion of the dummy gate electrode layer 122 is removed by an isotropic etching process.

Afterwards, as shown in FIG. 4F, a dielectric material is filled into the trench 147 and the planarization process is performed on the dielectric material to form a dielectric wall structure 148, in accordance with some embodiments. The planarization process may be a CMP process or an etch-back process to remove excess dielectric material outside the trench 147. As a result, the dielectric wall structure 148 is between the first fin structure 104a and the second fin structure 104b. In addition, the top surface of the dielectric wall structure 148 is substantially coplanar with the top surface of the dummy gate electrode layer 122 of the first dummy gate structure 118a. The protection layer 144 is still reaming and lines the sidewall surfaces of the dielectric wall structure 148.

The dielectric wall structure 148 has a top portion 148a and a bottom portion 148b, and the width of the top portion 148a is smaller than the width of the bottom portion 148b. The top surface of the top portion 148a has a top width Wt, and the bottom surface of the bottom portion 148b has a bottom width Wb. In some embodiments, the top width Wt is smaller than the bottom width Wb. In some embodiments, the difference between the bottom width Wb and the top width Wt is in a range from about 3 nm to about 10 nm. In addition, the remaining protection layer 144 is formed on the bottom portion 148b of the dielectric wall structure 148.

In addition, the bottom portion 148b of the dielectric wall structure 148 is in direct contact with the dummy gate dielectric layer 120. The bottom portion 148b of the dielectric wall structure 148 is isolated from the first fin structure 104a and the second fin structure 104b by the dummy gate dielectric layer 120.

Next, as shown in FIG. 4G, the remaining dummy gate electrode layer 122 of the first dummy gate structure 118a is removed to form a trench 151, in accordance with some embodiments. As a result, the dummy gate dielectric layer 120 and the remaining protection layer 144 are exposed.

The removal process may include one or more etching processes. For example, when the dummy gate electrode layer 122 is polysilicon, a wet etchant such as a tetramethylammonium hydroxide (TMAH) solution may be used to selectively remove the dummy gate electrode layer 122.

Afterwards, as shown in FIG. 4H, a portion of the dummy gate dielectric layer 120 is removed, in accordance with some embodiments. Another portion of the dummy gate dielectric layer 120 is remaining and between the first fin structure 104a and the second fin structure 104b.

The removal process may include one or more etching processes. In some embodiments, the dummy gate dielectric layer 120 is removed by using a plasma dry etching, a dry chemical etching, and/or a wet etching. After the removal process, the topmost surface of the dummy gate dielectric layer 120 is substantially coplanar with the topmost surface of the first fin structure 104a and the topmost surface of the second fin structure 104b.

Next, as shown in FIG. 41, the first semiconductor material layers 106 are removed to form nanostructures 108′ (or channel layers 108′) with the second semiconductor material layers 108, in accordance with some embodiments. As a result, gaps 153 are formed adjacent to the nanostructures 108′ (or channel layers 108′).

Afterwards, as shown in FIG. 4J, after the nanostructures 108′ are formed, the interfacial layer 154, the gate dielectric layer 156, and the gate electrode layer 158 are formed in the trench 151 and the gaps 153, in accordance with some embodiments.

After the interfacial layers 154, the gate dielectric layers 156, and the gate electrode material are formed, a planarization process such as CMP or an etch-back process may be performed. After the planarization process, the gate electrode layer 158 is divided into two portions by the dielectric wall structure 148 to form a first gate structure 162a and a second gate structure 162b.

After the nanostructures 108′ are formed, the first gate structure 162a and the second gate structure 162b are formed wrapped around the nanostructures 108′. The first gate structure 162a and the second gate structure 162b wrap around the nanostructures 108′ to form gate-all-around transistor structures in accordance with some embodiments. In some embodiments, the first gate structure 162a includes the interfacial layer 154, the gate dielectric layer 156, and the gate electrode layer 158. In some embodiments, the second gate structure 162b includes an interfacial layer 154, a gate dielectric layer 156, and the gate electrode layer 158.

In some embodiments, the interfacial layers 154 are oxide layers formed around the nanostructures 108′ and on the top of the base fin structure 105. In some embodiments, the interfacial layers 154 are formed by performing a thermal process.

In some embodiments, the gate dielectric layers 156 are formed over the interfacial layers 154, so that the nanostructures 108′ are surrounded (e.g. wrapped) by the gate dielectric layers 156. In addition, the gate dielectric layers 156 also cover the sidewalls of the gate spacers 126 and the inner spacers 134 in accordance with some embodiments. In some embodiments, the gate dielectric layers 156 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, another suitable high-k dielectric material, or a combination thereof. In some embodiments, the gate dielectric layers 156 are formed using chemical vapor deposition (CVD), atomic layer deposition (ALD), another applicable method, or a combination thereof.

In some embodiments, the first gate structure 162a and the second gate structure 162b are formed on the gate dielectric layer 156. In some embodiments, the first gate structure 162a and the second gate structure 162b are made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the first gate structure 162a and the second gate structure 162b are formed using chemical vapor deposition (CVD), atomic layer deposition (ALD), electroplating, another applicable method, or a combination thereof. Other conductive layers, such as work function metal layers, may also be formed in the first gate structure 162a and the second gate structure 162b, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

The dielectric wall structure 148 and the dummy gate dielectric layer 120 are between the nanostructures 108′ of the first gate structure 162a and the nanostructures 108′ of the second gate structure 162b. The dummy gate dielectric layer 122 is made of dielectric material, and the dielectric wall structure 148 is also made of dielectric material. Therefore, the first gate structure 162a is isolated from the second gate structure 162b by the dielectric wall structure 148 and the dummy gate dielectric layer 122. The bottom portion 148b of the dielectric wall structure 148 is isolated from one of the nanostructures 108′ by the dummy gate dielectric layer 120. The dummy gate dielectric layer 122 is in direct contact with the gate dielectric layer 156 of the first gate structure 162a. The dummy gate dielectric layer 120 has a U-shaped structure to surround the dielectric wall structure 148.

In some embodiments, the entirety of the dielectric wall structure 148 is above the top surface of the isolation structure 116. In some other embodiments, a portion of the dielectric wall structure 148 is lower than the top surface of the isolation structure 116. The portion of the dielectric wall structure 148 is lower than the bottommost nanostructure 108′.

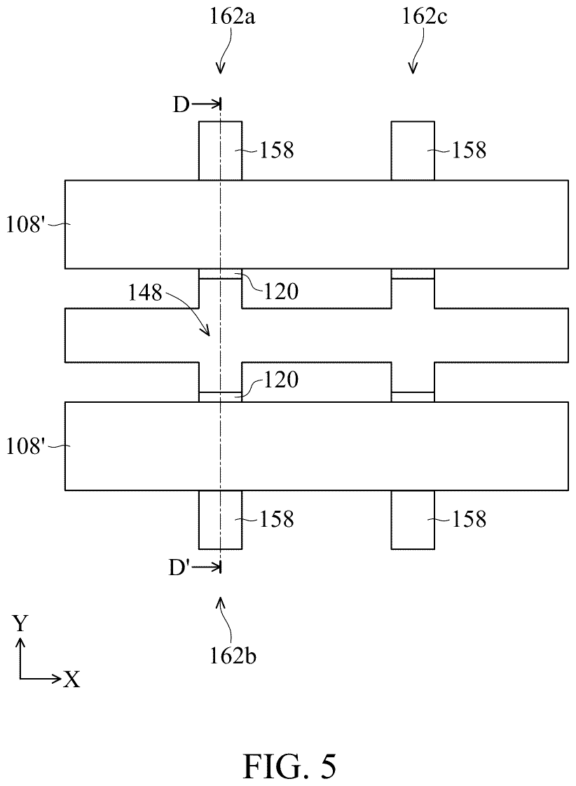

FIG. 5 shows a top-view representation of the semiconductor structure 100a along the line DD′ in FIG. 4J, in accordance with some embodiments. As shown in FIG. 5, the dielectric wall structure 148 is between the first gate structure 162a and the second gate structure 162b. The dielectric wall structure 148 is in direct contact with the dummy gate dielectric layer 120. The dummy gate dielectric layer 120 is between the dielectric wall structure 148 and the nanostructure 108′, and the dummy gate dielectric layer 120 is in direct contact with the nanostructure 108′.

In addition to along the second direction, the dielectric wall structure 148 further extends along the first direction, and therefore the dielectric wall structure 148 has a cross-shaped structure when seen from a top-view.

Since one side of the nanostructure 108′ is in direct contact with the dummy gate dielectric layer 122, rather than the gate electrode layer 158, the effective width (W_{eff}) of nanostructure 108′ (or channel layer 108′) is reduced. When the effective width (W_{eff}) of nanostructure 108′ (or channel layer 108′) is reduced, the current of the semiconductor layer 100a can be reduced for better power efficiency. In other words, the dielectric wall structure 148 extends along the second direction, and is close to the nanostructure 108′, so power consumption can be reduced. Therefore, the semiconductor layer 100a can applied in power efficiency device, and the performance of the semiconductor layer 100a is improved.

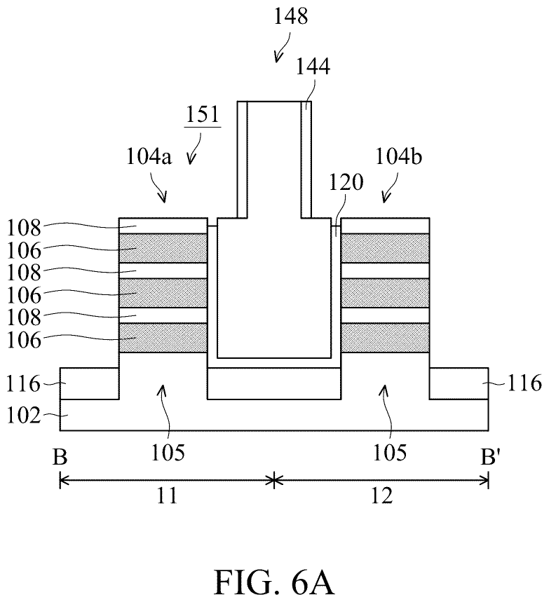

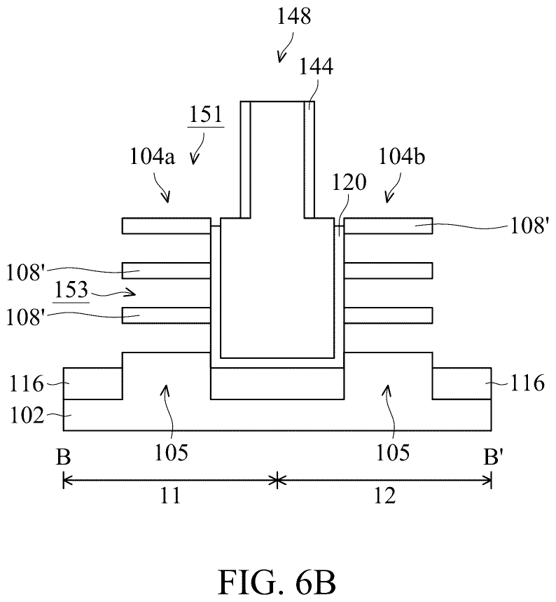

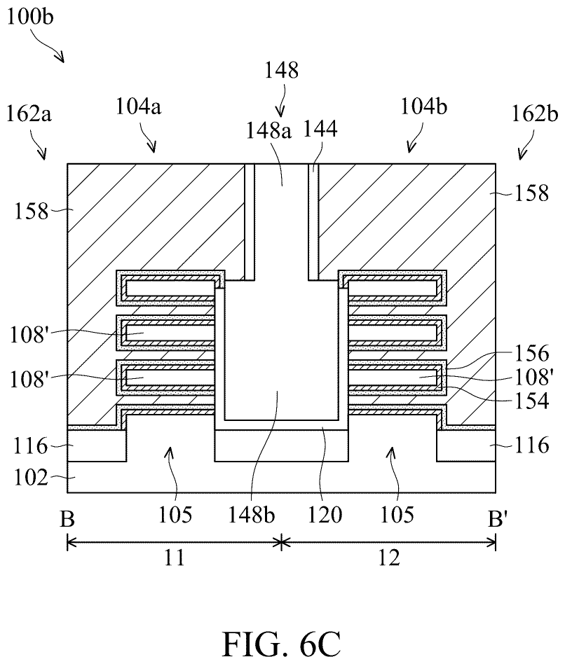

FIGS. 6A to 6C illustrate cross-sectional representations of various stages of manufacturing a semiconductor structure 100b shown along line B-B′ in FIG. 1E and FIG. 2, in accordance with some embodiments. The semiconductor structure 100b of FIGS. 6A-6C includes elements that are similar to, or the same as, elements of the semiconductor structure 100a of FIG. 4H.

FIG. 6A is are similar to, or the same as, FIG. 4H, the difference between FIG. 6A and FIG. 4H is that the topmost surface of the dummy gate dielectric layer 122 is lower than the topmost surface of the first fin structure 104a and the topmost surface of the second fin structure 104b. More specifically, the topmost surface of the dummy gate dielectric layer 122 is lower than the topmost surface of the second semiconductor material layer 108.

Next, as shown in FIG. 6B, the first semiconductor material layers 106 are removed to form nanostructures 108′ (or channel layers 108′) with the second semiconductor material layers 108, in accordance with some embodiments. As a result, gaps 153 are formed adjacent to the nanostructures 108′ (or channel layers 108′).

It should be noted that the topmost surface of the dummy gate dielectric layer 122 is lower than the topmost surface of the nanostructure 108′. In addition, the topmost surface of the dummy gate dielectric layer 122 is lower than the bottom surface of the protection layer 144.

Afterwards, as shown in FIG. 6C, the interfacial layer 154, the gate dielectric layer 156, and the gate electrode layer 158 are formed to wrap around the nanostructures 108′, in accordance with some embodiments.

After the interfacial layers 154, the gate dielectric layers 156, and the gate electrode material are formed, a planarization process such as CMP or an etch-back process may be performed. After the planarization process, the gate electrode layer 158 is divided into two portions by the dielectric wall structure 148 to form the first gate structure 162a and the second gate structure 162b.

The first gate structure 162a is isolated from the second gate structure 162b by the dielectric wall structure 148. The topmost surface of the dummy gate dielectric layer 120 is lower than the topmost surface of the nanostructure 108′.

The bottom portion 148b of the dielectric wall structure 148 is surrounded by the dummy gate dielectric layer 120, and the topmost surface of the dummy gate dielectric layer 120 is lower than the top surface of the bottom portion 148b of the dielectric wall structure 148. It should be noted that a portion of the gate electrode layer 148 is in a space between the bottom portion 148b of the dielectric wall structure 148 and the nanostructure 108′. In addition, the gate dielectric layers 156 is in direct contact with the dummy gate dielectric layer 120.

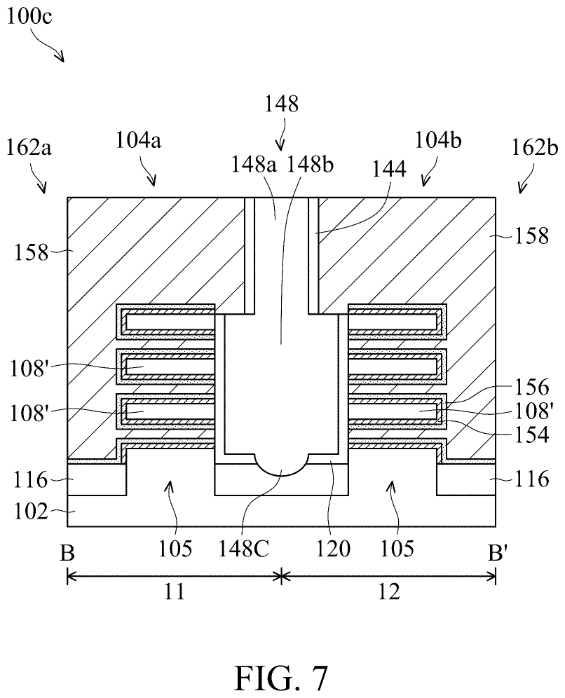

FIG. 7 illustrates a cross-sectional representation of a semiconductor structure 100c shown along line B-B′ in FIG. 1E and FIG. 2, in accordance with some embodiments. The semiconductor structure 100c of FIG. 7 includes elements that are similar to, or the same as, elements of the semiconductor structure 100a of FIG. 4J.

The difference between the FIG. 7 and FIG. 4J is that the dielectric wall structure 148 includes a protruding portion 148c, and the protruding portion 148c of the dielectric wall structure 148 is lower than the top surface of the isolation structure 116. Furthermore, the protruding portion 148c of the dielectric wall structure 148 is lower than the bottommost surface of the nanostructures 108′.

When the sidewall portion of the dummy gate electrode layer 122 is removed to form the trench 147, the exposed dummy gate dielectric layer 120 and the isolation structure 116 may be removed. Therefore, a recess (not shown) is formed, and the dielectric material is filled into the trench 147 and the recess to from the dielectric wall structure 148 with the protruding portion 148c.

In some embodiments, the protruding portion 148c of the dielectric wall structure 148 has a depth, and the depth is in a range from about 3 nm to about 10 nm measured from the top surface of the isolation structure 116.

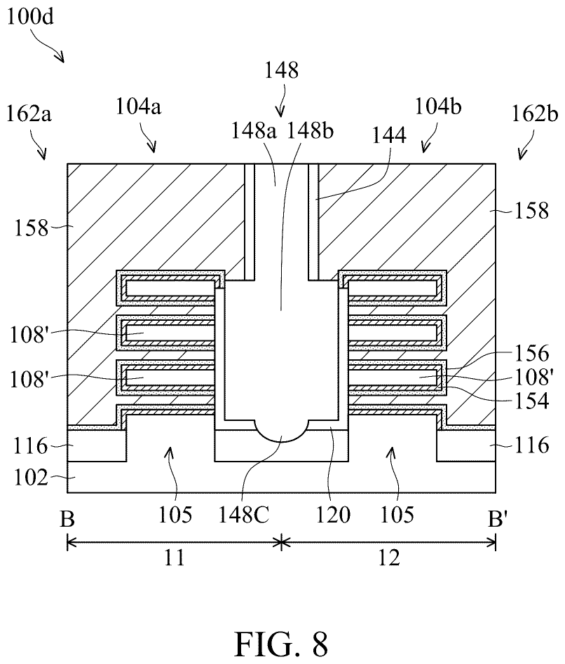

FIG. 8 illustrates a cross-sectional representation of a semiconductor structure 100d shown along line B-B′ in FIG. 1E and FIG. 2, in accordance with some embodiments. The semiconductor structure 100d of FIG. 8 includes elements that are similar to, or the same as, elements of the semiconductor structure 100a of FIG. 6C.

The difference between the FIG. 8 and FIG. 6C is that the dielectric wall structure 148 includes the protruding portion 148c, and the protruding portion 148c is lower than the top surface of the isolation structure 116. Furthermore, the protruding portion 148c is lower than the bottommost surface of the nanostructures 108′.

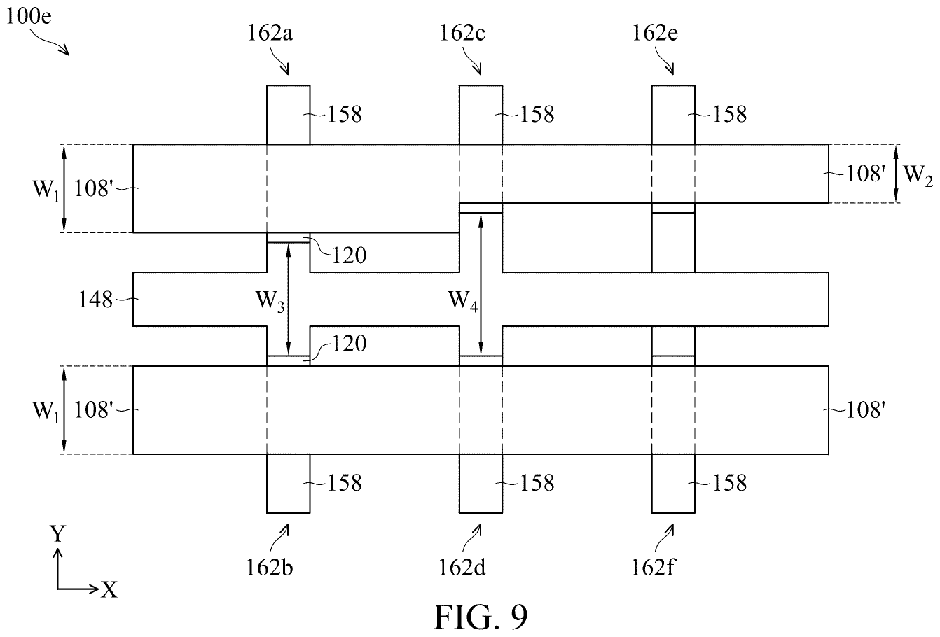

FIG. 9 shows a top-view representation of a semiconductor structure 100e, in accordance with some embodiments. As shown in FIG. 9, the dielectric wall structure 148 is between the first gate structure 162a and the second gate structure 162b.

The first fin structure 104a and the second fin structure 104b are formed along the first direction (e.g. x-direction). The first fin structure 104a has a first portion and a second portion. The first portion has the first width W₁ along the second direction (e.g. y-direction), and the second portion has the second width W₂ along the second direction (e.g. y-direction). In some embodiments, the first width W₁ is greater than the second width W₂. The second fin structure 104b has the first width W₁ along the along the second direction (e.g. y-direction).

The dielectric wall structure 148 extends along the first direction and the second direction. The dielectric wall structure 148 has a third width W₃ along the second direction, and a fourth width W₄ along the second direction. In some embodiments, the third width W₃ is smaller than the fourth width W₄.

Since the first fin structure 104a has different widths (W₁ and W₂) along the second direction, the dielectric wall structure 148 is close to the first fin structure 104a and also has different widths (W₃ and W₄).

The dielectric wall structure 148 extends along the first direction and the second direction, and has a cross-shaped structure when seen from a top-view.

The first gate structure 162a, the third gate structure 162c and the fifth gate structure 162e are parallel to each other along the second direction and are formed across the first fin structure 104a. The second gate structure 162b, the fourth gate structure 162d and the sixth gate structure 162f are parallel to each other along the second direction and are formed across the second fin structure 104b.

The first gate structure 162a is isolated from the second gate structure 162b by the portion of the dielectric wall structure 148 with the third width W₃. The third gate structure 162c is isolated from the fourth gate structure 162d by the portion of the dielectric wall structure 148 with the fourth width W₄.

The dummy gate dielectric layer 120 is between the dielectric wall structure 148 and the nanostructure 108′, and the dummy gate dielectric layer 120 is in direct contact with the nanostructure 108′.

Since one side of the nanostructure 108′ is in direct contact with the dummy gate dielectric layer 122, rather than the gate electrode layer 158, the effective width (W_{eff}) of nanostructure 108′ (or channel layer 108′) is reduced. When the effective width (W_{eff}) of nanostructure 108′ (or channel layer 108′) is reduced, the current of the semiconductor layer 100e can be reduced for better power efficiency. In other words, the dielectric wall structure 148 extends along the second direction, and is close to the nanostructure 108′, so power consumption can be reduced. Therefore, the semiconductor layer 100e can applied in power efficiency device, and the performance of the semiconductor layer 100e can be improved.

It should be noted that same elements in FIGS. 1A to 9 may be designated by the same numerals and may include similar or the same materials and may be formed by similar or the same processes; therefore such redundant details are omitted in the interest of brevity. In addition, although FIGS. 1A to 9 are described in relation to the method, it will be appreciated that the structures disclosed in FIGS. 1A to 9 are not limited to the method but may stand alone as structures independent of the method. Similarly, although the methods shown in FIGS. 1A to 9 are not limited to the disclosed structures but may stand alone independent of the structures. Furthermore, the nanostructures described above may include nanowires, nanosheets, or other applicable nanostructures in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structure includes a first fin structure and a second fin structure formed over a substrate. The first fin structure includes first nanostructures, and the second fin structure includes second nanostructures along a first direction (e.g. x-axis). A first gate structure formed over the first nanostructures along the second direction (e.g. y-direction) and a second gate structure formed along the second direction (e.g. y-direction). The dielectric wall structure is between the first fin structure and the second fin structure. The dummy gate dielectric layer is between the dielectric wall structure and the first fin structure. Since one side of the nanostructure is in direct contact with the dummy gate dielectric layer, the effective width (W_{eff}) of nanostructure (or channel layer) is reduced. When the effective width (W_{eff}) of nanostructure (or channel layer) is reduced, the current of the semiconductor layer can be reduced for better power efficiency. Therefore, the performance of the semiconductor structure is improved.

In some embodiments, a semiconductor structure is provided. The semiconductor structure includes first nanostructures formed over a substrate along a first direction, and second nanostructures formed over the substrate along the first direction. The semiconductor structure includes a first gate structure formed over the first nanostructures along a second direction, and a second gate structure formed over the second nanostructures along the second direction. The semiconductor structure also includes a dielectric wall structure between the first gate structure and the second gate structure along the second direction. The dielectric wall structure includes a top portion and a bottom portion, and a top width of a top surface of the top portion is smaller than a bottom width of a bottom surface of the bottom portion of the dielectric wall structure.

In some embodiments, a semiconductor structure is provided. The semiconductor structure includes first nanostructures and second nanostructures formed over a substrate along a first direction, and a first gate structure formed over the first nanostructures along a second direction. The semiconductor structure includes a second gate structure formed over the second nanostructures along the second direction. The semiconductor structure includes a dielectric wall structure between the first gate structure and the second gate structure. The dielectric wall structure includes a top portion and a bottom portion, the bottom portion is isolated from one of the first nanostructures by a dielectric layer.

In some embodiments, a method for forming a semiconductor structure is provided. The method includes forming a first fin structure and a second fin structure over a first region and a second region of a substrate, respectively, wherein the first fin structure includes first semiconductor material layers and second semiconductor material layers alternately stacked, and the second fin structure includes first semiconductor material layers and second semiconductor material layers alternately stacked. The method also includes forming a dummy gate structure over the first fin structure and the second fin structure, and removing a top portion of the dummy gate structure to form an opening. The method also includes forming a protection layer in the opening, and removing a bottom portion of the dummy gate structure to deepen a depth of the opening to form a recess. The method includes removing a sidewall portion of the dummy gate structure to enlarge a width of the recess to form a trench. The method includes filling a dielectric material into the trench to form a dielectric wall structure between the first fin structure and the second fin structure, wherein the dielectric wall structure is formed in a remaining dummy gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
first nanostructures formed over a substrate along a first direction;
second nanostructures formed over the substrate along the first direction;
a first gate structure formed over the first nanostructures along a second direction;
a second gate structure formed over the second nanostructures along the second direction; and
a dielectric wall structure between the first gate structure and the second gate structure along the second direction, wherein the dielectric wall structure comprises a top portion and a bottom portion, and a top width of a top surface of the top portion is smaller than a bottom width of a bottom surface of the bottom portion of the dielectric wall structure.

2. The semiconductor structure as claimed in claim 1, further comprising:
a dielectric layer between the dielectric wall structure and the first nanostructures, wherein the dielectric layer is in direct contact with the first nanostructures.

3. The semiconductor structure as claimed in claim 2, wherein a top surface of the dielectric layer is lower than a topmost surface of the first nanostructures.

4. The semiconductor structure as claimed in claim 1, further comprising:
an isolation structure formed over the substrate, wherein an entirety of the dielectric wall structure is above a top surface of the isolation structure.

5. The semiconductor structure as claimed in claim 4, wherein the dielectric wall structure comprises a protruding portion, and the protruding portion is lower than the top surface of the isolation structure.

6. The semiconductor structure as claimed in claim 1, wherein the first gate structure is isolated from the second gate structure by the dielectric wall structure.

7. The semiconductor structure as claimed in claim 1, wherein the dielectric wall structure further extends along the first direction, and the dielectric wall structure has a cross shaped structure when seen from a top-view.

8. The semiconductor structure as claimed in claim 1, wherein the first nanostructures comprise a first portion and a second portion, the first portion has a first width along the second direction, the second portion has a second width along the second direction, and the first width is greater than the second width.

9. The semiconductor structure as claimed in claim 8, wherein the dielectric wall structure has a first portion and a second portion, the first portion of the dielectric wall structure has a third width along the second direction, the second portion of the dielectric wall structure has a fourth width along the second direction, and the third width is smaller than the fourth width.

10. A semiconductor structure, comprising:
first nanostructures and second nanostructures formed over a substrate along a first direction;
a first gate structure formed over the first nanostructures along a second direction;
a second gate structure formed over the second nanostructures along the second direction; and
a dielectric wall structure between the first gate structure and the second gate structure, wherein the dielectric wall structure comprises a top portion and a bottom portion, the bottom portion is isolated from one of the first nanostructures by a dielectric layer.

11. The semiconductor structure as claimed in claim 10, further comprising:
a protection layer formed on a sidewall surface of the top portion of the dielectric wall structure.

12. The semiconductor structure as claimed in claim 10, wherein the dielectric wall structure has a first portion and a second portion, the first portion of the dielectric wall structure has a third width along the second direction, the second portion of the dielectric wall structure has a fourth width along the second direction, and the third width is smaller than the fourth width.

13. The semiconductor structure as claimed in claim 10, wherein the first gate structure comprises a first gate dielectric layer, and the first gate dielectric layer is in direct contact with the dielectric layer.

14. The semiconductor structure as claimed in claim 10, wherein the dielectric wall structure comprises a protruding portion, and the protruding portion is lower than a bottommost surface of the first nanostructures.

15. A method for forming a semiconductor structure, comprising:
forming a first fin structure and a second fin structure over a first region and a second region of a substrate, respectively, wherein the first fin structure comprises first semiconductor material layers and second semiconductor material layers alternately stacked, and the second fin structure comprises first semiconductor material layers and second semiconductor material layers alternately stacked;
forming a dummy gate structure over the first fin structure and the second fin structure;
removing a top portion of the dummy gate structure to form an opening;
forming a protection layer in the opening;
removing a bottom portion of the dummy gate structure to deepen a depth of the opening to form a recess;
removing a sidewall portion of the dummy gate structure to enlarge a width of the recess to form a trench; and
filling a dielectric material into the trench to form a dielectric wall structure between the first fin structure and the second fin structure, wherein the dielectric wall structure is formed in a remaining dummy gate structure.

16. The method for forming the semiconductor structure as claimed in claim 15, wherein the dummy gate structure comprises a dummy gate dielectric layer and a dummy gate electrode formed over the dummy gate dielectric layer, and the dummy gate dielectric layer is exposed by the trench after removing the sidewall portion of the dummy gate structure.

17. The method for forming the semiconductor structure as claimed in claim 16, further comprising:
removing the remaining dummy gate structure to expose a portion of the dummy gate dielectric layer.

18. The method for forming the semiconductor structure as claimed in claim 16, further comprising:
removing a portion of the dummy gate dielectric layer to expose a portion of the first fin structure and a portion of the second fin structure;
removing the first semiconductor material layers to form gaps; and
forming a gate structure in the gaps.

19. The method for forming the semiconductor structure as claimed in claim 15, further comprising:
forming an isolation structure over the substrate, wherein the first fin structure and the second fin structure extend above the isolation structure; and
recessing a portion of the isolation structure while removing the bottom portion of the dummy gate structure.

20. The method for forming the semiconductor structure as claimed in claim 15, wherein the dielectric wall structure has a top surface and a bottom surface, and a top width of the top surface is smaller than a bottom width of the bottom surface of the dielectric wall structure.
